(19) United States
(12) Patent Application Publication
(10) Pub. No.: US 2012/0049368 A1
(43) Pub. Date: Mar. 1, 2012

(54) SEMICONDUCTOR PACKAGE

(76) Inventor: SHINJI TANAKA, Tokyo (JP)

(21) Appl. No.: 13/197,189

(22) Filed: Aug. 3, 2011

(30) Foreign Application Priority Data
Sep. 1, 2010 (JP) 2010-195557

(51) Int. Cl. H01L 23/48

(52) U.S. Cl. 257/741; 257/774; 257/E23.011

(57) ABSTRACT

A semiconductor package according to the present invention is embedded with a plurality of silicon substrates including semiconductor elements, the semiconductor package including a through-silicon via in a first silicon substrate, in which a base material of a core substrate forming a package substrate has a linear expansion coefficient of 3 to 8 ppm/° C.

### INCORPORATION BY REFERENCE

This application is based upon and claims the benefit of priority from Japanese patent application No. 2010-195557, filed on Sep. 1, 2010, the disclosure of which is incorporated herein in its entirety by reference.

### BACKGROUND OF THE INVENTION

1. Technical Field

The present invention relates to a semiconductor package embedded with a plurality of silicon substrates including semiconductor elements.

2. Background Art

Since the invention of integrated circuits (ICs), semiconductor industries have been rapidly grown by continuous improvement in integration densities of various electronic components (e.g., a transistor, a diode, a resistor, and a capacitor). These improvement in integration densities have been accomplished by reducing a minimum feature size so that larger number of components are integrated in a predetermined area.

Those improvement in integration densities have been achieved in two dimensions (2D), and the volume of the components that are integrated is on the surface of a semiconductor wafer. The improvement in lithography has certainly brought about great improvement in forming 2D integrated circuits. However, the densities that can be improved in two dimensions have physical limitation. One of these limitation is a minimum size required to manufacture those components. Further, more complicated design is required with increasing number of devices included in one chip.

Various stacked packages employing wire bonding or through-silicon vias (TSVs) have been suggested as methods for mounting a plurality of silicon substrates on one package substrate.

A semiconductor package embedded with a plurality of silicon substrates according to related arts is shown in FIGS. 19 and 20. FIG. 19 shows a semiconductor package including silicon substrates connected by wire bonding. FIG. 20 shows a semiconductor package including silicon substrates laminated in a height direction through through-silicon vias.

However, the present inventors have found problems as follows in the semiconductor package embedded with the plurality of silicon substrates stated above.

Since the silicon substrates are connected by wire bonding in the semiconductor package shown in FIG. 19, it is not suitable for achieving high-speed transmission. Further, a thickness and an area of the package increase.

For example, Japanese Unexamined Patent Application Publication No. 2009-111392 discloses a stacked package including one or more semiconductor chips laminated on a package substrate.

However, the stacked package disclosed in Japanese Unexamined Patent Application Publication No. 2009-111392 achieves mounting by wire bonding. Thus, it is not suitable for a high-speed operation due to the inductance of the wire itself. Furthermore, mounting by wire bonding causes an increase in the thickness of the package.

FIG. 20 shows a package in which through-silicon vias (TSVs) are used to overcome the above problems. Shown in FIG. 20 is a semiconductor package including silicon substrates laminated in the height direction through through-silicon vias. However, since the silicon substrates are laminated in the height direction, the electrical connection length increases.

For example, Japanese Unexamined Patent Application Publication No. 2009-4723 discloses a through-silicon via chip stacked package which facilitates a chip selection. In the structure disclosed in Japanese Unexamined Patent Application Publication No. 2009-4723, a plurality of silicon substrates need to be stacked in the height direction to achieve mounting, which increases the thickness in the package. Further, a distance between the silicon substrates stacked in the height direction and a substrate of a package increases, which causes a problem of power feeding, for example.

Further, Japanese Unexamined Patent Application Publication No. 2004-186442 discloses a manufacturing method of a vertical power semiconductor chip using both surfaces of a silicon wafer as electrodes and being electrically conducted in a thickness direction. A semiconductor chip disclosed in Japanese Unexamined Patent Application Publication No. 2004-186442 has a similar structure as that disclosed in Japanese Unexamined Patent Application Publication No. 2009-4723. It is expected that a package substrate warps in a convex direction as a result of thermal process to connect a second silicon substrate to a package substrate due to a thermal expansion coefficient difference of a base material of the package substrate and a first silicon substrate that is embedded. This gives an influence to flatness (coplanarity) of the second silicon substrate connection surface, which results in a reduction in solder connection reliability. In particular, an increase in the size of the silicon substrate that is embedded causes serious problem since it causes larger warpage in the package substrate.

The thermal expansion coefficient difference between the silicon substrate and the package substrate causes warpage in the package substrate and reduction in solder connection reliability. Typically, a linear expansion coefficient of the base material of the core substrate forming the package substrate is 12 to 15 ppm/° C.

As described above, the stacked packages according to the related arts are not suitable for high-speed operations and increase the thickness of the package. Further, the package substrates are warped due to the thermal expansion coefficient difference between the silicon substrate and the package substrate, which decreases solder connection reliability.

### SUMMARY

The present invention has been made in order to solve the problem stated above, and aims to provide a semiconductor package having connection reliability by decreasing the electrical connection length among a plurality of silicon substrates, minimizing parasitic capacitance, and suppressing warpage of a whole package substrate.

An exemplary aspect of the present invention is a semiconductor package embedded with a plurality of silicon substrates including semiconductor elements, the semiconductor package including a through-silicon via in a first silicon substrate, in which a base material of a core substrate forming a package substrate has a linear expansion coefficient of 3 to 8 ppm/° C.

The first silicon substrate preferably includes a pad electrically connected to the through-silicon via.

Preferably, the pad is a copper pad.

Preferably, the first silicon substrate is electrically connected to a second silicon substrate through a micro via formed in the package substrate.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a cross-sectional view of a semiconductor package according to a first exemplary embodiment of the present invention;

FIG. 2 is a partially enlarged cross-sectional view of FIG. 1;

FIG. 3 is a partially enlarged cross-sectional view of FIG. 1;

FIG. 4 is a partial process diagram of the semiconductor package according to the first exemplary embodiment of the present invention;

FIG. 5 is a partial process diagram of the semiconductor package according to the first exemplary embodiment of the present invention;

FIG. 6 is a partial process diagram of the semiconductor package according to the first exemplary embodiment of the present invention;

FIG. 7 is a partial process diagram of the semiconductor package according to the first exemplary embodiment of the present invention;

FIG. 8 is a partial process diagram of the semiconductor package according to the first exemplary embodiment of the present invention;

FIG. 9 is a partial process diagram of the semiconductor package according to the first exemplary embodiment of the present invention;

FIG. 10 is a partial process diagram of a semiconductor package according to a second exemplary embodiment of the present invention;

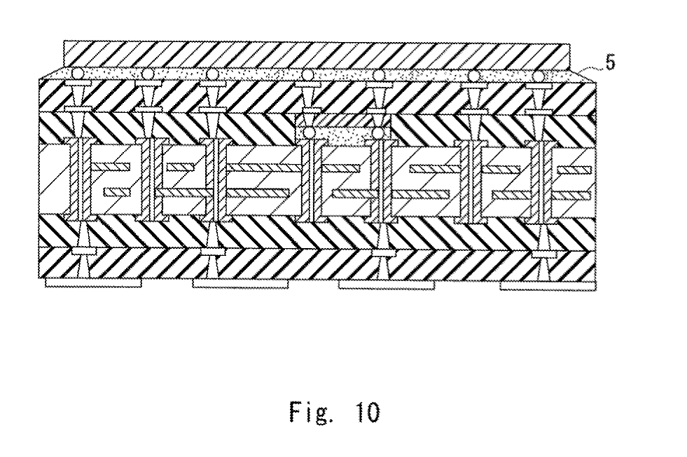

FIG. 11 is a partial process diagram of the semiconductor package according to the second exemplary embodiment of the present invention;

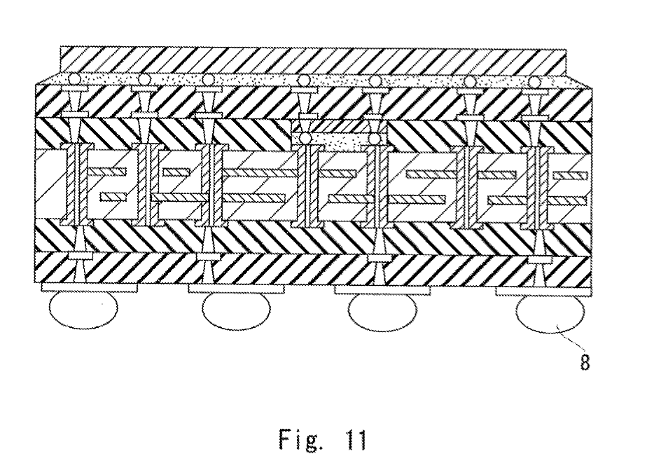

FIG. 12 is a partial process diagram of the semiconductor package according to the second exemplary embodiment of the present invention;

FIG. 13 is a partial process diagram of the semiconductor package using a ceramic material according to the first exemplary embodiment of the present invention;

FIG. 14 is a partial process diagram of the semiconductor package using a ceramic material according to the first exemplary embodiment of the present invention;

FIG. 15 is a partial process diagram of the semiconductor package using a ceramic material according to the first exemplary embodiment of the present invention;

FIG. 16 is a partial process diagram of the semiconductor package using a ceramic material according to the first exemplary embodiment of the present invention;

FIG. 17 is a partial process diagram of the semiconductor package using a ceramic material according to the first exemplary embodiment of the present invention;

FIG. 18 is a partial process diagram of the semiconductor package using a ceramic material according to the first exemplary embodiment of the present invention;

FIG. 19 is a semiconductor package according to a related art; and

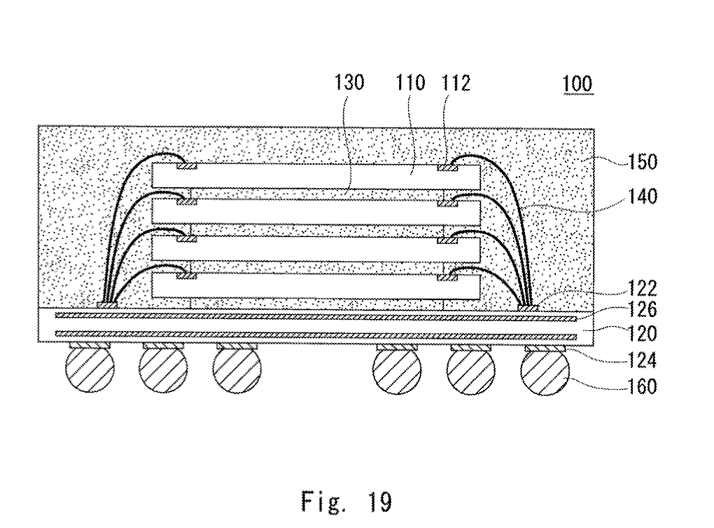

FIG. 20 is a semiconductor package according to a related art.

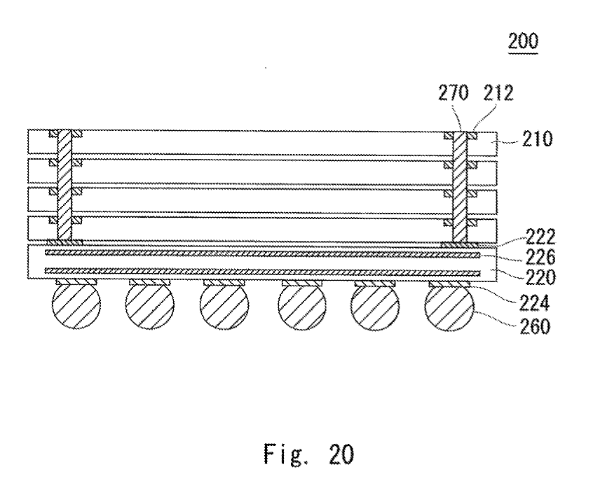

### EXEMPLARY EMBODIMENT

### First Exemplary Embodiment

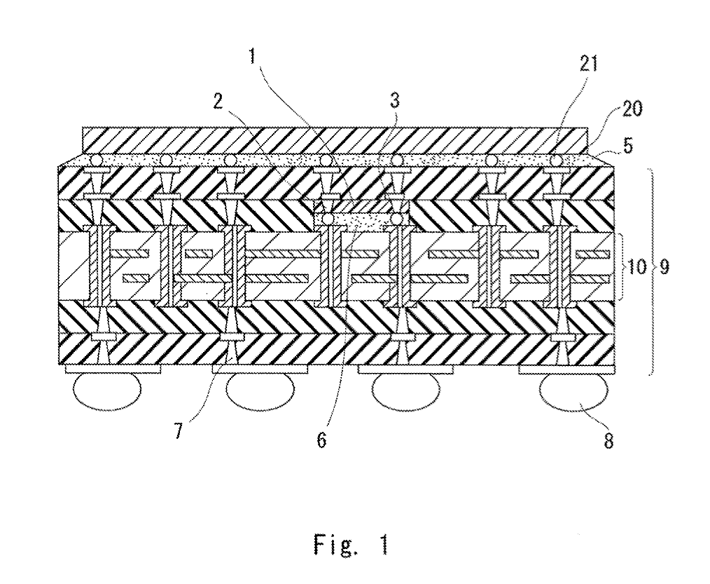

Referring to FIG. 1, a summary of a semiconductor package according to a first exemplary embodiment of the present invention will be described. FIG. 1 is a cross-sectional view of a semiconductor package according to the first exemplary embodiment.

As shown in FIG. 1, a silicon substrate 1 embedded in a substrate includes through-silicon vias 2, and is electrically connected to a second silicon substrate 20 through micro vias 7 of a package substrate. Further, a base material forming a core substrate 10 has a linear expansion coefficient of 3 to 8 ppm/° C.

The base material having a linear expansion coefficient lower than 3 ppm/° C. is not preferable in terms of reliability since this linear expansion coefficient greatly differs from a thermal expansion coefficient of a typical printed wiring board (12 to 16 ppm/° C.) in terms of connection reliability in secondary mounting of this package substrate on the typical printed wiring board. The base material having a linear expansion coefficient over 8 ppm/° C. is not preferable as well since it causes large warpage in the package substrate due to the thermal expansion coefficient difference between the silicon substrate and the package substrate.

As shown in FIG. 1, rear surface pads 3 are arranged in the silicon substrate 1, and solder balls 21 of the second silicon substrate are embedded in an underfill 5 of the first silicon substrate. Further, an underfill 6 of the second silicon substrate is arranged under the silicon substrate, and BGA balls 8 are arranged under the micro vias 7.

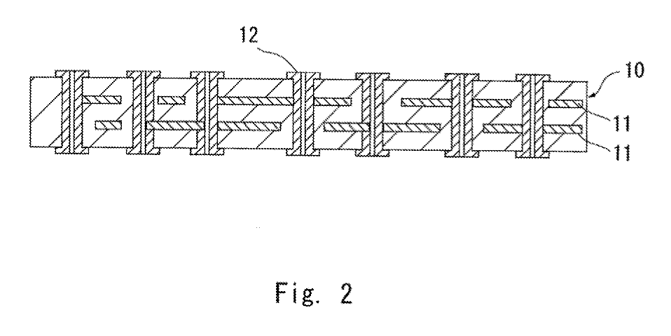

FIG. 2 is an enlarged cross-sectional view of the core substrate 10. FIG. 2 shows the core substrate 10 including plane layers 11 of a power supply or ground in inner layers and through holes 12 for connection. The build-up substrate 9 includes the core substrate 10 and build-up layers.

A material having a linear expansion coefficient of 3 to 8 ppm/° C. is used as the base material forming the core substrate 10. By using the base material having the linear expansion coefficient of 3 to 8 ppm/° C., the connection reliability in the second silicon substrate can be secured while suppressing the warpage in the package substrate caused by the package substrate embedded with the silicon substrate.

Specifically, a material such as an aramid substrate obtained by impregnating an aramid fiber non-woven fabric with thermosetting resin such as epoxy is preferably used.

In general, a material having a linear expansion coefficient of 12 to 15 ppm/° C. is used as the base material of the core substrate 10. However, a manufacturing method of the semiconductor package is the same even when a material having low linear expansion coefficient is employed. The detailed description of the manufacturing method is omitted since it is known to a person skilled in the art and has no direct relation with the present invention.

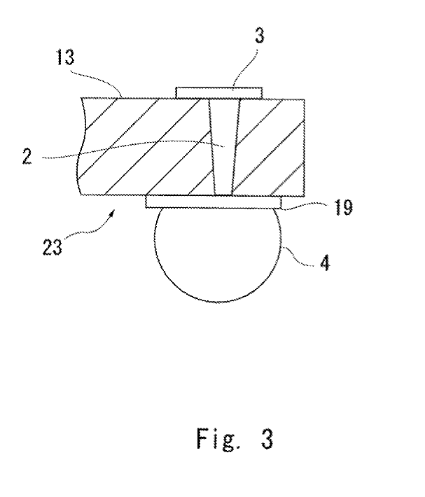

FIG. 3 is a detailed diagram of the first silicon substrate 1. In the first silicon substrate 1, active elements or passive elements to achieve a predetermined function are formed on a circuit surface 23, and are connected to an external electrode 19 through a circuit pattern. The external electrode 19 includes a solder ball for connection 4. In FIG. 3, the elements and the circuit patterns are omitted.

Further, the copper pad 3 is provided through the through-silicon via 2 on the side of a rear surface 13 which is the opposite surface from the surface of the solder ball 4. The solder ball 4 may be made of any one of tin-silver-copper alloy, eutectic solder of tin-lead, gold-tin and the like.

Next, a typical manufacturing method of the through-silicon vias 2 will be briefly described. Vertical holes are formed in predetermined positions of the silicon substrate by etching, and insulating films are formed on the surface of the vertical holes. Seed metal layers are formed on the insulating films, thereafter the through-silicon vias 2 are formed by electrolytic plating. A typical method performs chemical polishing on the side of the rear surface of the silicon substrate to expose the through-silicon vias 2, and then forms copper pads 3 for external connection also on the rear surface.

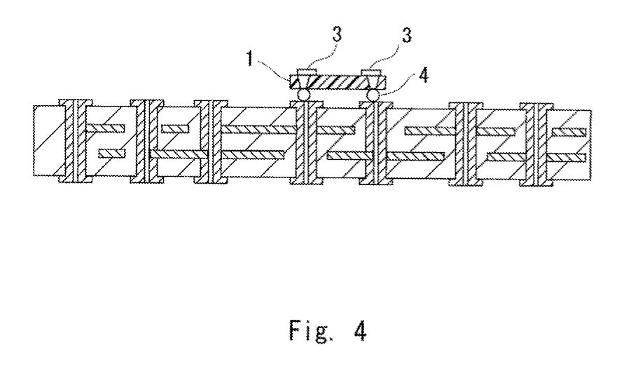

FIG. 4 is a state diagram in which the first silicon substrate 1 including the through-silicon vias 2 are mounted on the core substrate 10. A wide difference in the linear expansion coefficient between the core substrate 10 and the first silicon substrate 1 causes warpage in the core substrate 10 in the convex direction. This warpage can be suppressed by using a material having the linear expansion coefficient of 3 to 8 ppm/° C. as the base material of the core substrate 10.

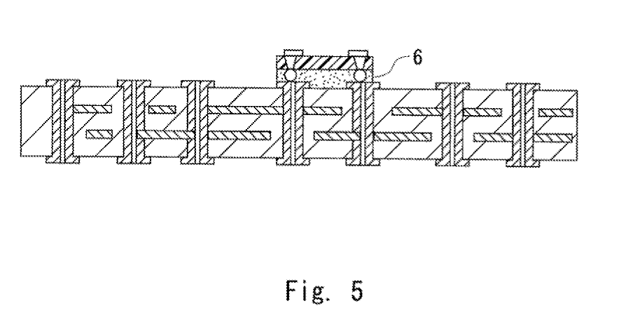

FIG. 5 is a state diagram in which a gap between the core substrate 10 and the first silicon substrate 1 is filled with the underfill resin 6 and is cured at a predetermined temperature for the purpose of improving connection reliability and maintaining the shape.

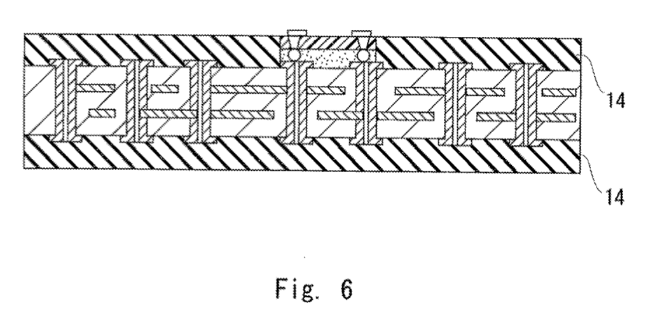

FIG. 6 is a state diagram in which film-shape build-up resin are laminated to form a first insulating layer 14. A part of the build-up resin on which the first silicon substrate 1 is mounted is cut out in advance so that the size of the cut-out part becomes larger than that of the first silicon substrate 1 by about 1 mm.

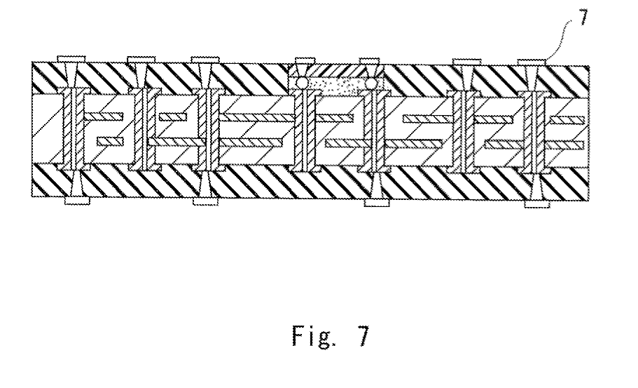

FIG. 7 is a diagram showing micro vias 7 formed in the first insulating layer 14. After the first insulating layer 14 is drilled by a laser beam and underlying metal is formed by electroless copper plating, patterns are formed by a plating resist, thereby forming the micro vias 7 by pattern plating at the same time pattern circuits are formed.

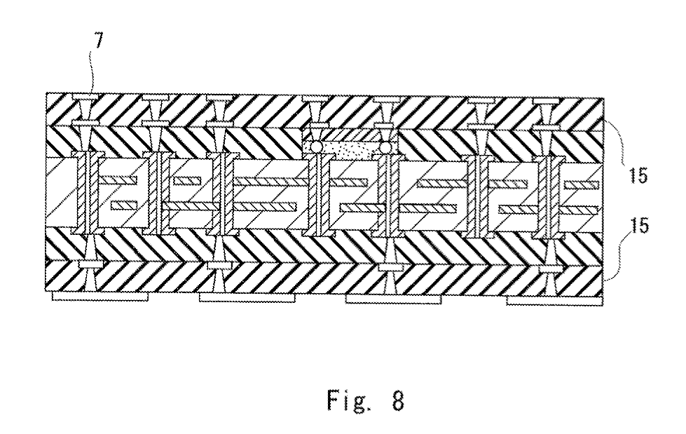

FIG. 8 is a state diagram in which a second insulating layer 15 and the micro vias 7 are formed in the similar way as in FIG. 7. At this time, the same position as the rear surface copper pads 3 on the through-silicon vias 2 exposed to the rear surface of the first silicon substrate 1 is drilled by a laser beam, and the micro vias 7 are formed in the same method, thereby achieving electrical connection. Lands of the micro vias 7 are exposed on the surface of the build-up substrate 9. In order to make the pads serve as mounting pads, the surfaces of the pads are treated with electroless nickel-gold plating, electroless nickel-paradium-gold plating, or water-soluble preflux (Organic Surface preservative) so as to achieve high solder wettability.

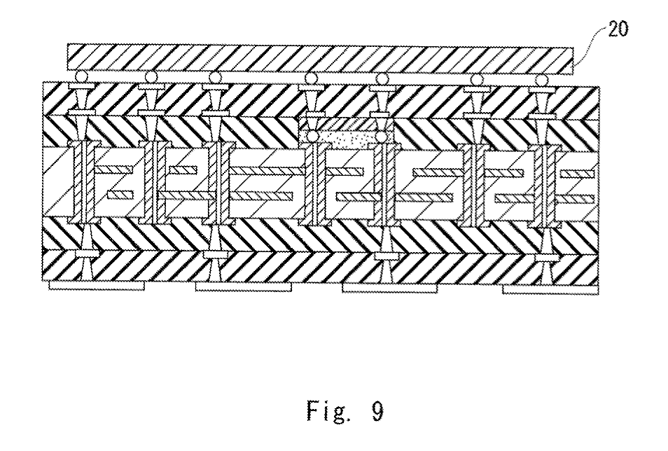

FIG. 9 is a state diagram showing the second silicon substrate 20 mounted on the build-up substrate 9 in a face-down manner. The second silicon substrate 20 includes solder balls 21 for flip-chip connection.

As described above, detailed description of the configuration of the build-up substrate used as the package substrate is omitted, since it is known to a person skilled in the art and has no direct relation with the present invention.

The first silicon substrate 1 may include passive elements including a capacitor, a resistor, and an inductor formed therein, and the second silicon substrate 20 may be a large-scale integrated circuit such as a memory and a CPU.

### Second Exemplary Embodiment

A basic structure of a second exemplary embodiment according to the present invention is similar to that of the first exemplary embodiment. In the second exemplary embodiment, productivity of a build-up substrate which is a package substrate can further be improved.

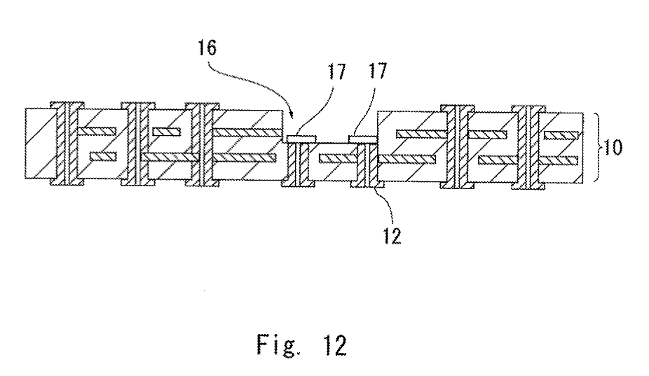

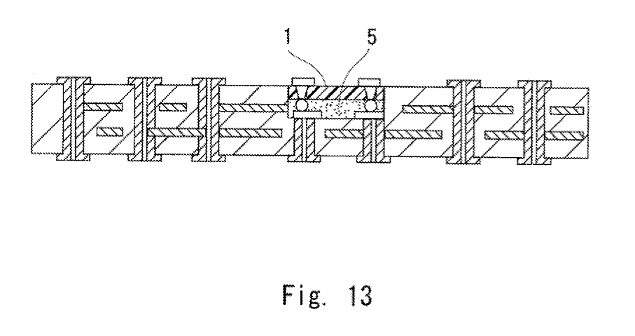

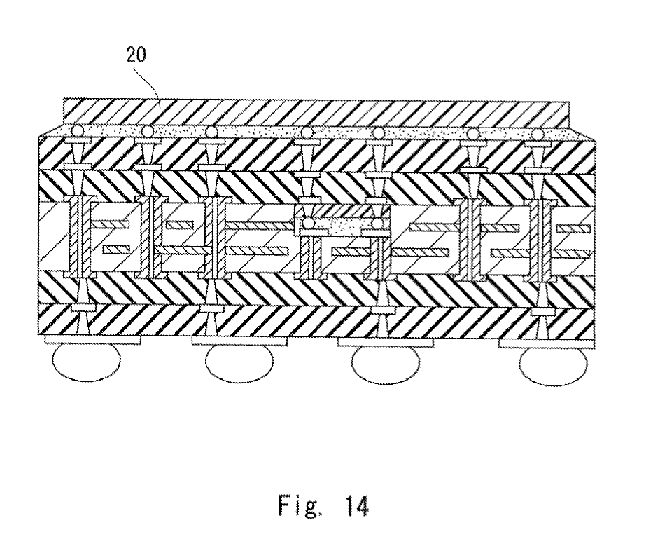

The structure according to the second exemplary embodiment is shown in FIGS. 12 to 14.

In FIG. 12, a first silicon substrate 1 is embedded in a core substrate 10 of a build-up substrate 9. At this time, pads 17 for mounting the first silicon substrate are formed in an inner layer of the core substrate 10. After the core substrate 10 is formed, a cavity 16 for mounting the first silicon substrate is provided to expose the pads 17. Then the first silicon substrate 1 is mounted in the pads 17. The process of forming build-up layers and the following processes are similar to the manufacturing method shown in FIG. 8.

While the basic structure according to the second exemplary embodiment is described above, a ceramic substrate may be employed instead of the build-up substrate which is the package substrate.

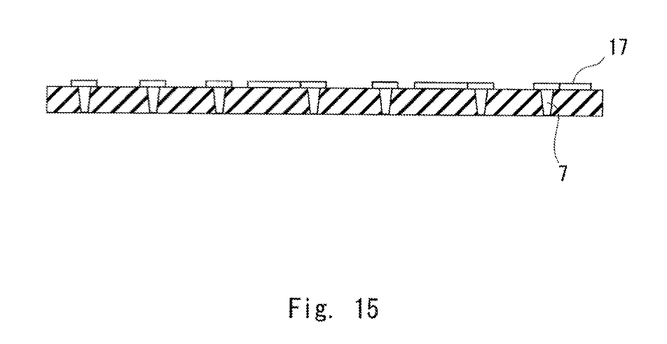

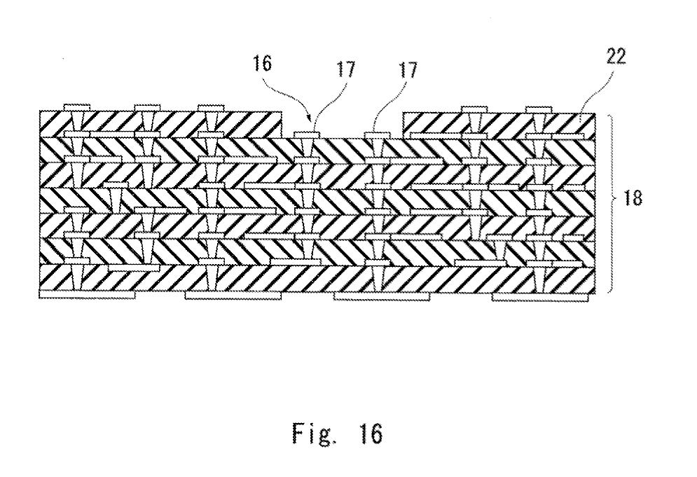

This structure is shown in FIGS. 15 to 18. The ceramic material has a linear expansion coefficient of 3 to 8 ppm/° C.

Green sheets 22 each having the thickness of 0.1 mm to 0.2 mm including the micro vias 7 and the pattern circuits formed therein are laminated for a predetermined number of layers in a ceramic substrate 18, and are collectively sintered, to form a ceramic wiring board 18.

In the second exemplary embodiment, the cavity 16 is provided in an area of the surface layer where the first silicon substrate is mounted, to expose the pad 17 for mounting the first silicon substrate provided in the inner layer.

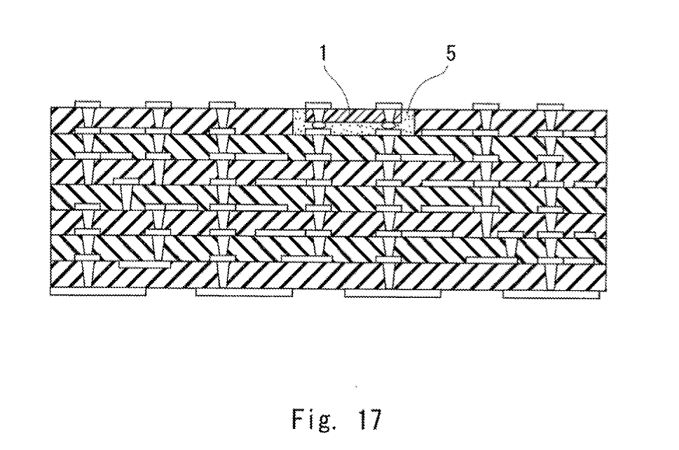

FIG. 17 is a state diagram in which the cavity 16 is filled with the underfill resin 5 after the first silicon substrate 1 is mounted.

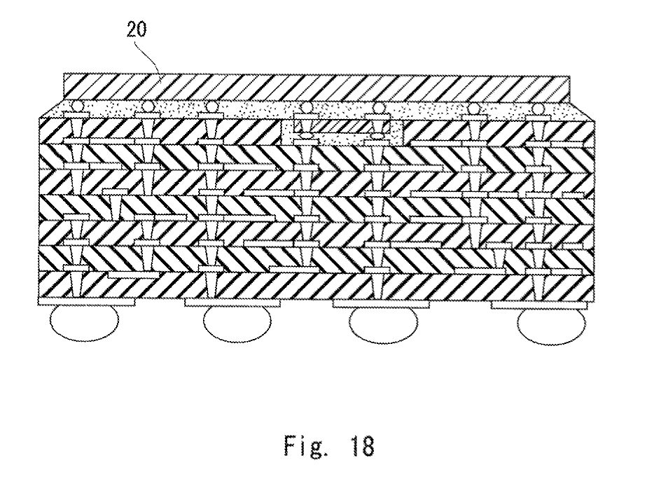

Next, the surface pads of the ceramic substrate and rear surface copper pads 3 formed in the rear surface of the first silicon substrate 1 are aligned in the height direction by polishing, thereafter a second silicon substrate 20 is mounted in a face-down manner (FIG. 18).

The ceramic material may be a glass ceramic material that can be collectively sintered at low temperature in place of alumina.

While the above exemplary embodiments employ solder balls 4 as the external terminal connected to the core substrate 10, other methods may be employed including pressure bonding by a gold bump or conductive resin (ACF). The connection method is selected in consideration of cure temperature of the insulating layers or connection temperature of the second silicon substrate. Similarly, pressure bonding by a gold bump or conductive resin (ACF) may be used as the external terminal of the second silicon substrate 20 in place of solder balls.

While the above exemplary embodiments employ the BGA balls 8 as the external terminal of the semiconductor package, they can be replaced with LGA (Land Grid Array) socket mounting pads.

As described above, in the second exemplary embodiment, through vias are provided in the silicon substrate that is embedded, which minimizes the electrical connection length to the second silicon substrate and achieves small parasitic capacitance of the transmission path. Further, a material having the linear expansion coefficient of the base material of the core substrate forming the package substrate of 3 to 8 ppm/° C. is selected, which is close to that of the silicon substrate. This suppresses warpage of the whole package substrate caused by the package substrate embedded with the silicon substrate, and ensures the connection reliability of the second silicon substrate.

Specifically, a material having the linear expansion coefficient that is close to that of the first silicon substrate that is embedded is used as the linear expansion coefficient of the core substrate, which makes it possible to increase the connection reliability of the second silicon substrate.

Furthermore, since the first silicon substrate includes the through-silicon vias, the first silicon substrate can be electrically connected to the package substrate and the second silicon substrate with the smallest path.

Furthermore, since the first silicon substrate includes the through-silicon vias and is embedded in the substrate, a thin semiconductor package with small mounting area can be obtained.

The present invention is not limited to the exemplary embodiments described above, but can be changed as appropriate without departing from the spirit of the present invention.

According to the present invention, the silicon substrate including through-silicon vias is embedded in the package substrate, which minimizes the electric connection length to the package substrate or the second silicon substrate, and reduces parasitic capacitance of the transmission path. Further, the linear expansion coefficient of the base material forming the package substrate is specified and a material having the linear expansion coefficient that is close to that of the silicon substrate is selected, which makes it possible to suppress the warpage in the whole package substrate and ensures the connection reliability of the second silicon substrate.

While the invention has been particularly shown and described with reference to exemplary embodiments thereof, the invention is not limited to these exemplary embodiments. It will be understood by those of ordinary skill in the art that various changes in form and details may be made therein without departing from the spirit and scope of the present invention as defined by the claims.

What is claimed is:

1. A semiconductor package embedded with a plurality of silicon substrates including semiconductor elements, the semiconductor package comprising a through-silicon via in a first silicon substrate, wherein
a base material of a core substrate forming a package substrate has a linear expansion coefficient of 3 to 8 ppm/° C.

2. The semiconductor package according to claim 1, wherein the first silicon substrate includes a pad electrically connected to the through-silicon via.

3. The semiconductor package according to claim 2, wherein the pad is a copper pad.

4. The semiconductor package according to claim 1, wherein the first silicon substrate is electrically connected to a second silicon substrate through a micro via formed in the package substrate.
